(19) United States
(12) Patent Application Publication
(10) Pub. No.: US 2026/0143762 A1
(43) Pub. Date: May 21, 2026

(54) METAL-OXIDE-SEMICONDUCTOR FIELD-EFFECT TRANSISTOR WITH INTEGRATED BURIED OXIDE AND P-SHIELD LAYERS

(71) Applicant: Renesas Electronics Corporation, Tokyo (JP)

(72) Inventors: Meng Chia LEE, Dallas, TX (US); Dilip Madhav RISBUD, San Jose, CA (US)

(73) Assignee: Renesas Electronics Corporation, Tokyo (JP)

(21) Appl. No.: 18/955,629

(22) Filed: Nov. 21, 2024

(51) Int. Cl. H01L 29/06; H01L 21/04; H01L 29/16; H01L 29/66; H01L 29/78

(52) U.S. Cl. CPC H10D 62/109; H10D 12/031; H10D 30/66; H10D 62/8325; H10P 30/2042; H10P 30/21

(57) ABSTRACT

A semiconductor structure includes a silicon carbide semiconductor substrate of a first conductivity type, having an upper surface and a bottom surface. A drift layer of the first conductivity type is positioned on the upper surface of the semiconductor substrate. A pair of source regions of the first conductivity type is disposed on the drift layer. A first semiconductor region of the first conductivity type disposed on a center portion of the drift layer is sandwiched between the pair of source regions. Laterally abutting a bottom portion of the first semiconductor region is a pair of second semiconductor regions of a second conductivity type opposite to the first conductivity. Embedded within the first semiconductor region is a third semiconductor region of the second conductivity type. An oxide layer is located, at least partially, within the first semiconductor region, extending above an upper surface of the first semiconductor region.

### BACKGROUND

The present disclosure generally relates to the field of semiconductor devices, and more particularly to silicon carbide (SiC) metal-oxide-semiconductor field-effect transistors (MOSFETs).

SiC MOSFETs have garnered significant attention in recent years due to their superior performance characteristics compared to traditional silicon devices. SiC MOSFETs exhibit high breakdown voltages, excellent thermal conductivity, and high switching speeds, making them particularly suitable for high-power and high-temperature applications, such as in electric vehicles, renewable energy systems, and industrial motor drives.

One challenge in the design of SiC MOSFETs is the optimization of their performance parameters, including on-resistance, switching losses, and thermal stability. The integration of buried oxide (BOX) layers has been identified as a promising approach to enhance device performance. The BOX layer serves multiple functions, including the reduction of parasitic capacitance, improvement of electrical isolation between device layers, and the enhancement of the substrate's thermal properties.

In addition to the BOX layer, the incorporation of P-type shield regions can further improve the performance of SiC MOSFETs. These P-shield regions help to mitigate the electric field distribution within the device, which can reduce the likelihood of breakdown and improve overall reliability. The interaction between the BOX layer and P-shield regions is critical in optimizing the electric field, thus allowing for better control over the device characteristics.

Despite advancements in the field, opportunities still exist for improved SiC MOSFET structures that can maximize efficiency and reliability while minimizing manufacturing complexity.

### SUMMARY

According to an embodiment of the present disclosure, a semiconductor structure includes a semiconductor substrate of a first conductivity type having an upper surface and a bottom surface, the semiconductor substrate including silicon carbide. The semiconductor substrate further includes a drift layer of the first conductivity type positioned on the upper surface of the semiconductor substrate, a pair of source regions of the first conductivity type disposed on the drift layer, a first semiconductor region of the first conductivity type located above a center portion of the drift layer such that the first semiconductor region is sandwiched between the pair of source regions, a pair of second semiconductor regions of a second conductivity type opposite to the first conductivity type laterally abutting a bottom portion of the first semiconductor region, a third semiconductor region of the second conductivity type embedded within the first semiconductor region, and an oxide layer located, at least partially, within the first semiconductor region and extending above an upper surface of the first semiconductor region.

According to another embodiment of the present disclosure, a semiconductor structure includes a semiconductor substrate of a first conductivity type, a drift layer of the first conductivity type disposed above an upper surface of the semiconductor substrate, a first semiconductor region of the first conductivity type disposed above a center portion of the drift layer, a pair of second semiconductor regions of a second conductivity type laterally abutting a bottom portion of the first semiconductor region, a pair of source regions of the first conductivity type adjacent to the first semiconductor region and disposed, at least partially, above the second semiconductor region, a third semiconductor region of the second conductivity type disposed within a recessed central portion of the first semiconductor region, a first portion of an oxide layer disposed above and in contact with the third semiconductor region, the first portion of the oxide layer having a first thickness, and a second portion of the oxide layer disposed above an upper surface of the first semiconductor region and, at least partially, above an upper surface of the pair of source regions, the second portion of the oxide layer having a second thickness.

According to yet another embodiment of the present disclosure, a semiconductor structure includes a semiconductor substrate of a first conductivity type, a drift layer of the first conductivity type disposed above an upper surface of the semiconductor substrate, a first semiconductor region of the first conductivity type disposed above a center portion of the drift layer, a pair of second semiconductor regions of a second conductivity type laterally abutting a bottom portion of the first semiconductor region, a pair of source regions of the first conductivity type adjacent to the first semiconductor region and disposed, at least partially, above the second semiconductor region, a third semiconductor region of the second conductivity type disposed within a recessed central portion of the first semiconductor region, an oxide of uniform thickness layer laterally extending above an upper surface of the third semiconductor region, an upper surface of the first semiconductor region and, at least partially, above an upper surface of a pair of source drain regions, and a gate electrode disposed above the oxide layer.

### BRIEF DESCRIPTION OF THE DRAWINGS

The following detailed description, given by way of example and not intended to limit the embodiments described herein, will best be appreciated in conjunction with the accompanying drawings, in which:

FIG. 1 is a cross-sectional view of a semiconductor structure depicting an intermediate step during a semiconductor manufacturing process, according to an embodiment of the present disclosure;

FIG. 2 is a cross-sectional view of the semiconductor structure after conducting a thermal annealing process, according to an embodiment of the present disclosure;

FIG. 3A is a cross-sectional view of the semiconductor structure depicting a first step during a process of forming an oxide layer, according to an embodiment of the present disclosure;

FIG. 3B is a cross-sectional view of the semiconductor structure depicting a second step during the process of forming the oxide layer, according to an embodiment of the present disclosure;

FIG. 4A is a cross-sectional view of the semiconductor structure depicting a first step during an alternate process of forming the oxide layer, according to an embodiment of the present disclosure;

FIG. 4B is a cross-sectional view of the semiconductor structure depicting a second step during the alternate process of forming the oxide layer, according to an embodiment of the present disclosure;

FIG. 4C is a cross-sectional view of the semiconductor structure depicting a third step during the alternate process of forming the oxide layer, according to an embodiment of the present disclosure;

FIG. 5 is a cross-sectional view of the semiconductor structure after forming a gate electrode, according to an embodiment of the present disclosure;

FIG. 6 is a cross-sectional view of the semiconductor structure after forming an interlevel dielectric layer above the gate electrode, a top metal layer, and a conductive material, according to an embodiment of the present disclosure;

FIG. 7 is cross-sectional view of a semiconductor structure depicting an alternate configuration of the oxide layer, according to an embodiment of the present disclosure; and

FIG. 8 is a flowchart depicting operational steps for the fabrication of the semiconductor structure, according to an embodiment of the present disclosure.

The drawings are not necessarily to scale. The drawings are merely schematic representations, not intended to portray specific parameters of the embodiments in the present disclosure. The drawings are intended to depict typical embodiments of the present disclosure. In the drawings, like numbering represents like elements.

### DETAILED DESCRIPTION

Detailed embodiments of the claimed structures and methods are disclosed herein; however, it can be understood that the disclosed embodiments are merely illustrative of the claimed structures and methods that may be embodied in various forms. The claimed structures and methods may, however, be embodied in many different forms and should not be construed as limited to the exemplary embodiments set forth herein. In the description, details of various conventional features and techniques may be omitted to avoid unnecessarily obscuring the presented embodiments.

For purposes of the description hereinafter, terms such as “upper”, “lower”, “right”, “left”, “vertical”, “horizontal”, “top”, “bottom”, and derivatives thereof shall relate to the disclosed structures and methods, as oriented in the drawing figures. Terms such as “above”, “overlying”, “atop”, “on top”, “positioned on” or “positioned atop” mean that a first element, such as a first structure, is present on a second element, such as a second structure, wherein intervening elements, such as an interface structure may be present between the first element and the second element. The term “direct contact” means that a first element, such as a first structure, and a second element, such as a second structure, are connected without any intermediary conducting, insulating or semiconductor layers at the interface of the two elements.

In the interest of not obscuring the presentation of embodiments of the present disclosure, in the following detailed description, some processing steps or operations that may be ordinary in the art may have been combined together for presentation and for illustration purposes and in some instances may have not been described in detail. In other instances, some processing steps or operations that may be ordinary in the art may not be described at all. It should be understood that the following description is rather focused on the distinctive features or elements of various embodiments of the present disclosure.

Planar SiC MOSFETs encounter several significant challenges, including high gate capacitance that negatively impacts switching speeds, uneven electric field distribution leading to increased breakdown risks, limited thermal management capabilities, and complex manufacturing processes requiring multiple masks. Embodiments of the present disclosure provide a SiC MOSFET that addresses these challenges by incorporating a thick oxide layer located in the middle of the junction field-effect transistor (JFET) region. This thick oxide layer can be positioned above the SiC surface or embedded within the SiC, resulting in a planar surface. A P-type shield implant is placed underneath the thick oxide layer to further enhance the electric field distribution within the device and reduce the likelihood of breakdown.

Thus, the incorporation of the thicker oxide layer can reduce gate capacitance, resulting in improved switching speeds. Additionally, the P-type shield can effectively lower both the electric field and gate oxide capacitance, while also enabling an increased JFET dose due to the presence of the P-type shield implant. Furthermore, the design simplifies the fabrication process by requiring only one additional mask for the implementation of both the thick oxide layer and P-shield. Collectively, these advancements contribute to a more efficient and reliable SiC MOSFET.

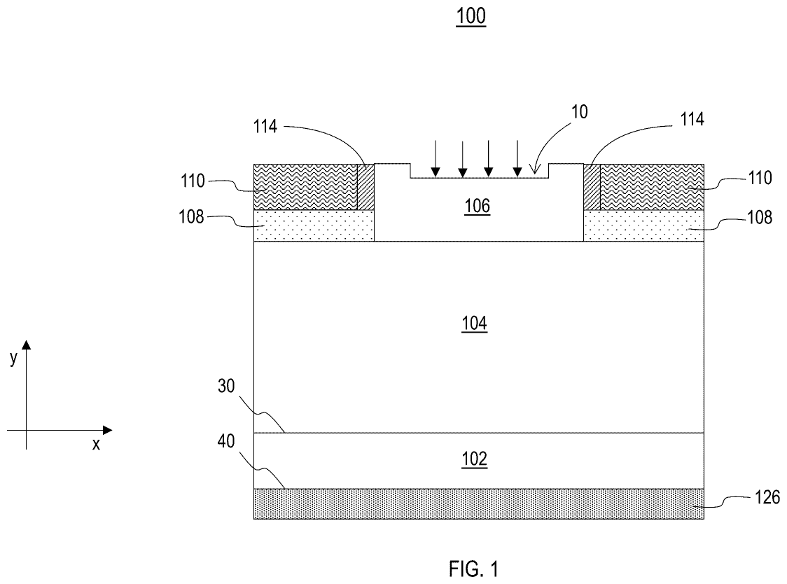

Embodiments by which the SiC MOSFET with integrated buried oxide and P-shield layers can be formed is described in detail below by referring to the accompanying drawings in FIGS. 1-8.

Referring now to FIG. 1, a cross-sectional view of a semiconductor structure 100 is shown depicting an intermediate step during a semiconductor manufacturing process, according to an embodiment of the present disclosure.

At this step of the manufacturing process, semiconductor structure 100 includes a semiconductor substrate (hereinafter “substrate”) 102. Substrate 102 includes an upper surface 30 and a bottom surface 40. A drift region 104 is located on the upper surface 30 of the substrate 102. A first semiconductor region 106 is positioned above a middle section of the drift layer 104. A bottom portion of the first semiconductor region 106 is laterally abutted by a pair of second semiconductor regions (hereinafter “second semiconductor regions”) 108 disposed above the drift region 104, while a top portion of the first semiconductor region 106 is laterally abutted by a pair of channel regions (hereinafter “channel regions”) 114 disposed above the second semiconductor region 108. The channel regions 114 are established within the semiconductor structure 100 during its operational phase. Semiconductor structure 100 further includes a pair of source regions (hereinafter “source regions”) 110. Each channel region 114 is laterally adjacent to a source region 110 on one side and to the first semiconductor region 106 on the opposite side.

Substrate 102 includes a doped semiconductor layer of a first conductivity type made of silicon carbide (SiC) with an added impurity concentration. An initial thickness of substrate 102 can be of approximately 350 μm. The substrate 102 can be grinded to approximately 100 mm during backside processing steps. The impurity concentration in the substrate 102 can vary between approximately 1×10¹⁸ cm⁻³ to approximately 1×10¹⁹ cm⁻³. The first conductivity type can be P-type or N-type. It should be noted that substrate 102 serves as a drain region for the semiconductor structure 100, providing a pathway for current flow. While the drain region is integrated within the substrate 102, in some embodiments it can be engineered with distinct doping characteristics or other modifications to meet specific designs, enhance performance or manage thermal properties.

Drift region 104 is formed above and in contact with the upper surface 30 of substrate 102. The drift region 104 is made of silicon carbide with an added impurity concentration that is lower than the impurity concentration of substrate 102. In general, drift region 104 can be formed by epitaxial growth by using the semiconductor substrate 102 as seed layer. Terms such as “epitaxial growth and/or deposition” and “epitaxially formed and/or grown” refer to the growth of a semiconductor material on a deposition surface of a semiconductor material, in which the semiconductor material being grown has the same or substantially similar crystalline characteristics as the semiconductor material of the deposition surface.

In some embodiments, drift region 104 can be formed by chemical vapor deposition (CVD) of the semiconductor material (i.e., SiC). A thickness of the drift region 104 is determined by the device voltage rating. For example, the thickness of the drift region 104 can be approximately 10 μm for 1.2 kV rated devices. The impurity concentration of the drift region 104 can be approximately 1×10¹⁶ cm⁻³ for 1.2 kV rated devices. However, the impurity concentration of the drift region 104 is not limited to this value and may be in a range of approximately 1×10¹⁴ cm⁻³ to approximately 1×10¹⁷ cm⁻³ depending on the device voltage rating.

First semiconductor region 106 can serve as a junction field effect transistor (JFET) region of the semiconductor structure 100. First semiconductor region 106 is formed above and in contact with the drift region 104. In some instances, first semiconductor region 106 can be formed with a higher donor doping of the first conductivity type that can vary between approximately 1×10¹⁵ cm⁻³ and approximately 1×10¹⁸ cm⁻³. A thickness of the first semiconductor region 106 is approximately 0.1 μm to approximately 3.5 μm.

Second semiconductor region 108 includes a heavily-doped semiconductor layer of the second conductivity type. The second conductivity type can be P-type or N-type. In embodiments in which the second conductivity type is P-type, the second semiconductor region 108 can be referred to as a deep P-region. A thickness of the second semiconductor region 108 is approximately 0.1 μm to approximately 1.0 μm. The impurity concentration of the second semiconductor region 108 is approximately 1×10¹⁷ cm⁻³ or higher.

Source regions 110 formed on opposite sides of the first semiconductor region 106 can have a thickness varying between approximately 0.1 μm and approximately 0.5 μm. Source regions 110 may include a heavily-doped semiconductor layer of the first conductivity type. A dopant concentration of source regions 114 can vary, for example, between 1×10¹⁹ cm⁻³ and 1×10²¹ cm⁻³.

In one or more embodiments, the different impurity or dopant concentrations in the semiconductor structure 100 can be achieved by ion implantation or diffusion of impurity ions or dopants. For example, in embodiments in which the first conductivity type is N-type and the second conductivity type is P-type, N-type dopants such as phosphorus (P) or arsenic (As) can be implanted into one or more semiconductor layers of the semiconductor structure 100 to form N-type doped semiconductor regions, while P-type dopants such as boron (B), aluminum (Al) or gallium (Ga) can be implanted into one or more semiconductor layers of semiconductor structure 100 to form P-type doped semiconductor regions.

In an embodiment, a bottom metal layer 126 can be formed on the bottom surface 40 of the substrate 102. The bottom metal layer 126 serves as a drain terminal or drain electrode that provides electrical (ohmic) contact with substrate 102.

With continued reference to FIG. 1, a recess 10 is formed within the first semiconductor region 106 followed by an ion implantation process. The process of forming the recess 10 may typically involve exposing a pattern on a photoresist layer, transferring the pattern to a hardmask layer (not shown) and then to the first semiconductor region 106 using lithography and reactive-ion etching (RIE) processing. In some embodiments, a sloped SiC etch may be performed to create recess 10 within the first semiconductor region 106. In these cases, recess 10 can exhibit a sloped or tilted profile.

After forming the recess 10, the ion implantation process is conducted on an upper surface of the first semiconductor region 106 exposed by recess 10. During the ion implantation process dopant ions of the second conductivity type are introduced into the expose portion of the first semiconductor region 106. Standard ion implantation techniques can be used to introduce the second conductivity type dopant ions into the first semiconductor region 106.

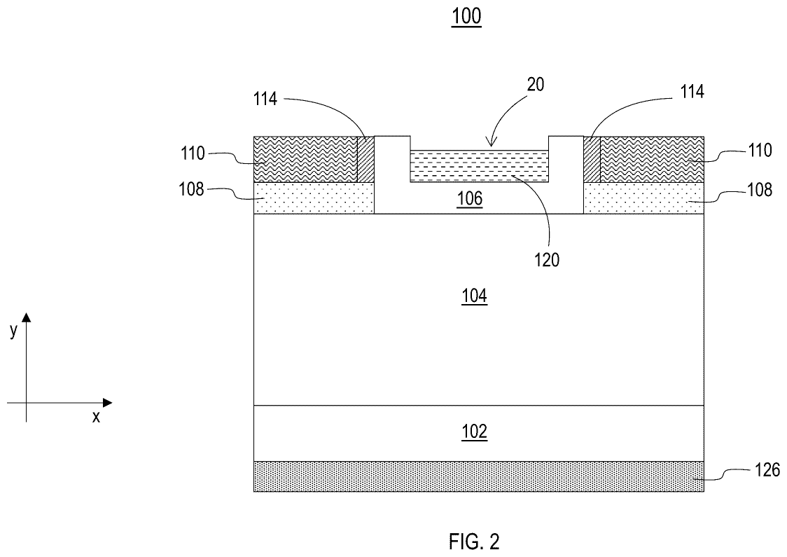

Referring now to FIG. 2, a cross-sectional view of the semiconductor structure 100 is shown after conducting a thermal annealing process to form a third semiconductor region 120 of the second conductivity type, according to an embodiment of the present disclosure.

The process of forming the third semiconductor region 120 starts with the ion implantation process described in FIG. 1. During the ion implantation process, dopant ions of the second conductivity type embed themselves into a crystal lattice of a central portion of the first semiconductor region 106, with a depth and concentration controlled by adjusting the ion energy and dosage. The thermal annealing step is performed to repair any lattice damage from the implantation process and to activate the dopant ions. Consequently, third semiconductor region 120 is formed within the first semiconductor region 106 with an impurity concentration of the second conductivity type varying, for example, between approximately 1×10¹⁹ cm⁻³ and approximately 1×10²¹ cm⁻³. A thickness of the third semiconductor region 120 can vary between approximately 0 mm to approximately 3 mm. In embodiments in which the second conductivity type is P-type, the third semiconductor region 120 can be referred to as P-type shield region or simply P-shield. P-type shield regions can enhance electric field distribution within the semiconductor structure 100. In an embodiment, a space 20 remains above the formed third semiconductor region 120.

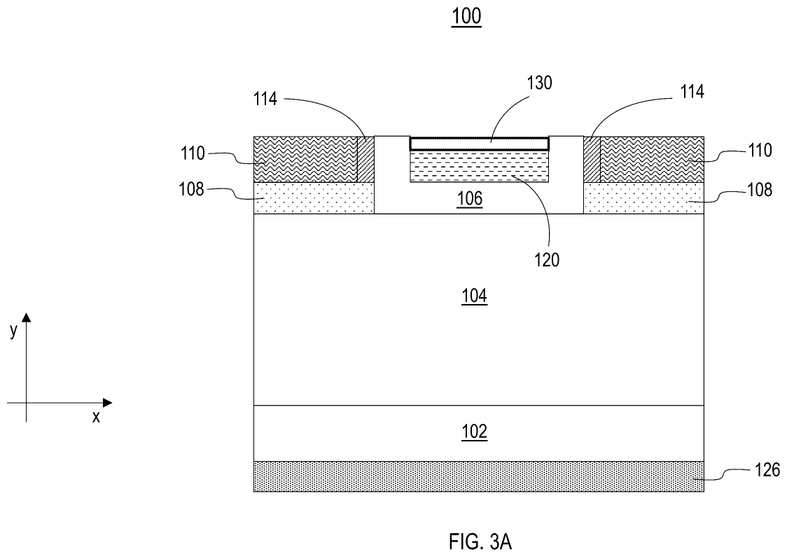

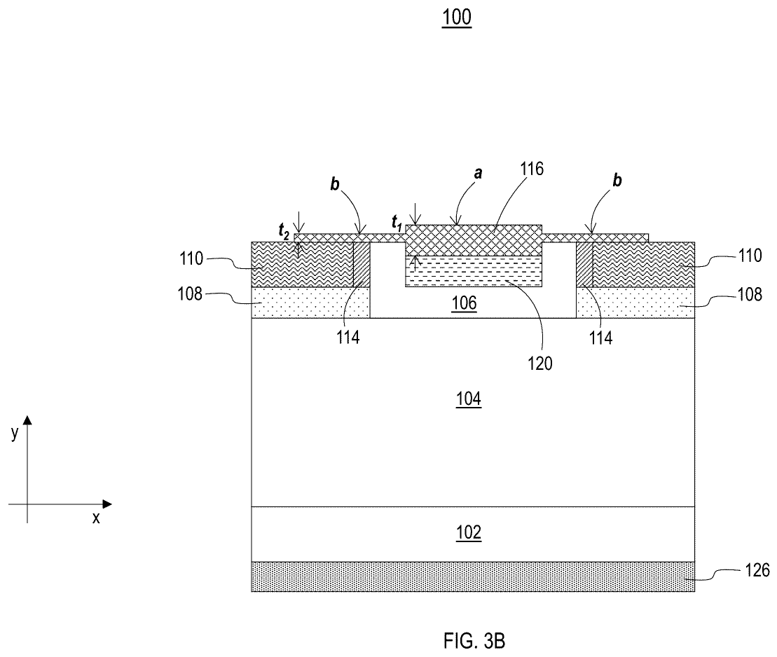

Referring now to FIGS. 3A-3B simultaneously, cross-sectional views of the semiconductor structure 100 are shown depicting a first process to form an oxide layer 116, according to an embodiment of the present disclosure.

In one embodiment, a first step of the first process to form the oxide layer 116 includes forming a polysilicon layer 130 within the space 20 shown in FIG. 2. The polysilicon layer 130 is formed in a way such that the deposited polysilicon material substantially fills the entire space 20. The polysilicon layer 130 can be typically deposited using techniques such as Chemical Vapor Deposition (CVD) or Low-Pressure Chemical Vapor Deposition (LPCVD). After depositing the polysilicon layer 130, an etch-back process is performed to achieve a desired thickness and planarization of the polysilicon layer 130. The etch-back process is intended to remove excess polysilicon from the surface while ensuring that the desired amount remains in place. This helps create a flat, uniform surface that is critical for subsequent oxidation. As a result, as depicted in FIG. 3A, a top surface of the polysilicon layer 130 is substantially flushed with a top surface of the first semiconductor region 106.

FIG. 3B depicts a second and final step of the first process to form the oxide layer 116. Specifically, in this embodiment, after the deposition of the polysilicon layer 130 and subsequent etch-back for planarization, an oxidation process is conducted to form the oxide layer 116. The thermal oxidation process typically involves heating a silicon-containing substrate in an oxygen-rich environment to form a silicon dioxide (SiO₂) layer on its surface. In general, this process occurs in a high-temperature furnace, where the substrate is exposed to either pure oxygen or water vapor at temperatures ranging from 800° C. to 1200° C. As the silicon reacts with oxygen, a dense and uniform oxide layer is formed, which serves multiple purposes including acting as an insulator, defining the gate oxide, and providing a protective barrier against contaminants. A thickness of the oxide layer 116 can be controlled by adjusting the oxidation time and temperature.

In the depicted embodiment, the oxide layer 116 includes a first portion a having a first thickness t₁ and a second portion b having a second thickness t₂. As depicted in FIG. 3B, the first thickness t₁ is greater than the second thickness t₂. Thus, the first portion a of the oxide layer 116 is partially embedded within the first semiconductor region 106 and in direct contact with the third semiconductor region 120. In an embodiment, the first thickness t₁ can vary between approximately 10 nm and approximately 500 nm, while the second thickness t₂ can vary between approximately 10 nm and approximately 100 nm.

To achieve the oxide layer 116 with a thicker middle portion a while keeping the lateral portions b thinner, different parameters during the thermal oxidation process can be controlled, for example, an oxidation profile, a temperature gradient, an oxidation time and gas flow. In other embodiments, a conformal oxide deposition such as chemical vapor deposition (CVD) can be implemented instead of thermal oxidation to achieve the thicker center portion a of the oxide layer 116.

After forming the oxide layer 116, an etch-back process is typically conducted to remove excess oxide material from the semiconductor structure 100. Specifically, the etch-back process removes the oxide layer 116 from areas where electrical contact is needed, such as source regions 110, that will connect to other components of the device, as depicted in FIG. 3B.

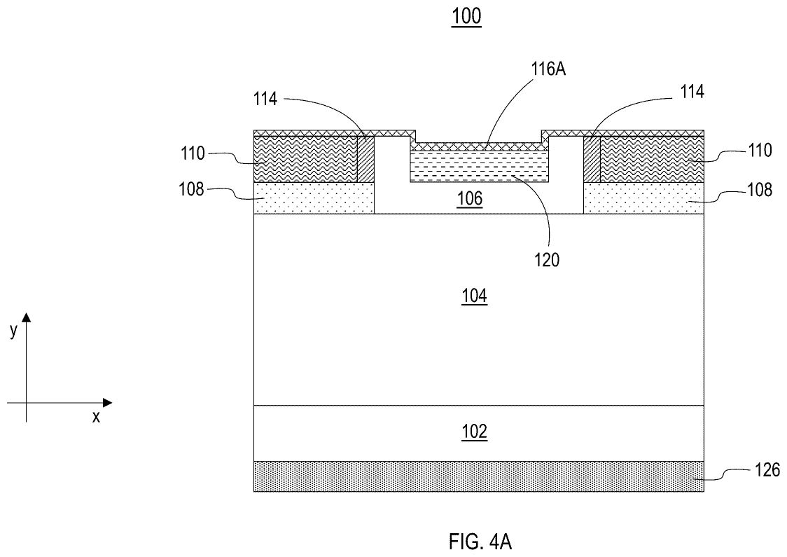

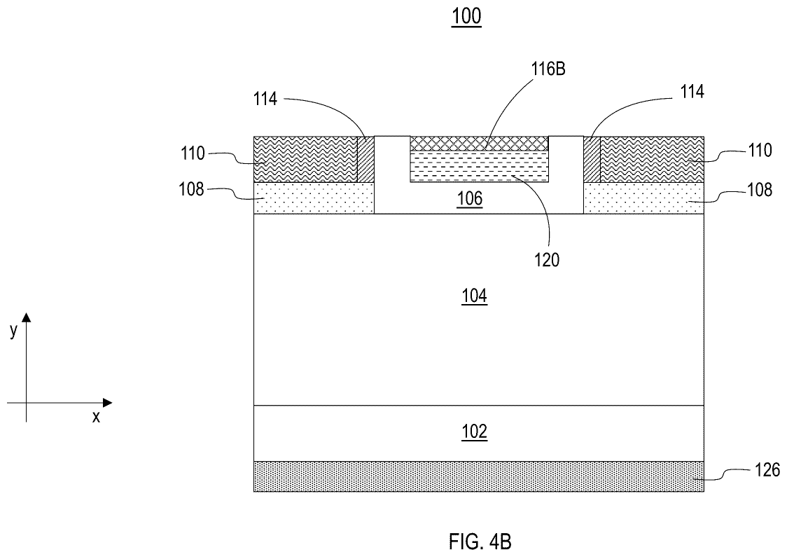

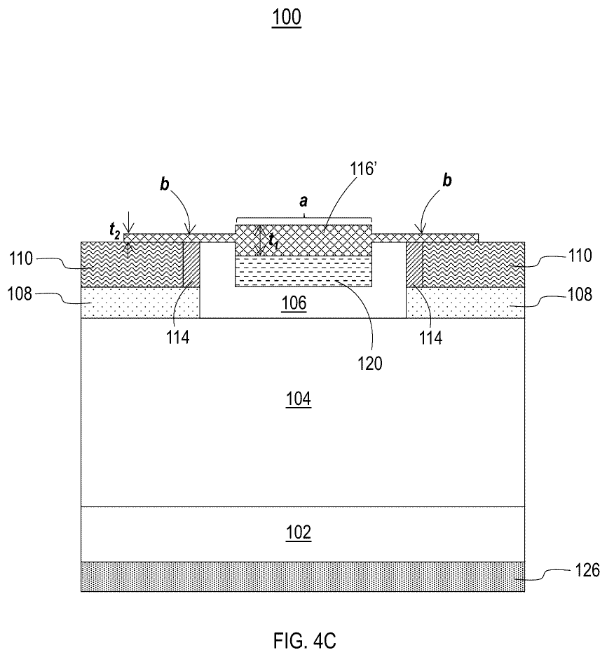

Referring now to FIGS. 4A-4C simultaneously, cross-sectional views of the semiconductor structure 100 are shown depicting a second process to form the oxide layer 116, according to an embodiment of the present disclosure.

In this embodiment, an alternate second process is used to form the oxide layer 116. The first step of the second process includes conducting a first thermal oxidation process on the semiconductor structure 100. The first thermal oxidation process is conducted after the activation anneal step described in FIG. 2 to form the third semiconductor region 120. During the first thermal oxidation process silicon from silicon-containing regions reacts with oxygen forming a dense and uniform initial oxide layer 116A above upper surfaces of the semiconductor structure 100. Specifically, the initial oxide layer 116A uniformly covers uppermost surfaces of the first semiconductor region 106, third semiconductor regions 120, channel regions 114 and source regions 110, as depicted in FIG. 4A. The initial oxide layer 116A conformally forms within the space 20 depicted in FIG. 2. A thickness of the initial oxide layer 116A can be controlled by adjusting the oxidation time and temperature. This initial oxide layer 116A serves as a foundation for subsequent oxide layers and can also act as an insulator. In an embodiment, a thickness of the initial oxide layer 116A can vary between approximately 10 nm and approximately 100 nm.

FIG. 4B depicts a second step of the second process to form the oxide layer 116. In this step, after the first thermal oxidation process, a thicker oxide layer 116B can be deposited above the initial oxide layer 116A using, for example, Plasma-Enhanced Chemical Vapor Deposition (PECVD). In this step, silane (SiH₄) or other silicon-containing gases are introduced into a plasma chamber. The plasma enhances the chemical reactions, resulting in the deposition of a uniform silicon dioxide (SiO₂) layer at relatively low temperatures. Following the deposition of the thicker oxide layer 116B, an etch-back process is performed to remove excess oxide material and achieve a planarized surface. As depicted in FIG. 4B, the initial oxide layer 116A (FIG. 4A) and the thicker oxide layer 116 substantially fills the space 20 (shown in FIG. 2) remaining above the third semiconductor region 120. The etch-back process can involve dry etching (such as Reactive Ion Etching) or wet etching techniques. The goal is to create a smooth and even surface, which is critical for subsequent processing steps.

FIG. 4C depicts the third and final step of the second process to form the oxide layer 116. After the deposition and planarization process described in FIG. 4B, a second thermal oxidation process is conducted on the semiconductor structure 100. In this step, the substrate is heated in an oxygen-rich environment again to grow a thicker oxide layer specifically for the gate region. The resulting oxide layer 116′ is substantially the same as the oxide layer 116 described above with reference to FIG. 3B. Accordingly, the oxide layer 116′ has similar first portion a having the first thickness t₁ and second portion b having second thickness t₂, with the first thickness t₁ being larger than the second thickness t₂.

In one or more embodiments, the thicker portion a of the oxide layers 116, 116′ in the gate area contributes to improved capacitance, reduced leakage, higher breakdown voltage, enhanced reliability, better control of short-channel effects, and greater thermal stability, all of which collectively enhance the performance and longevity of the MOSFET device.

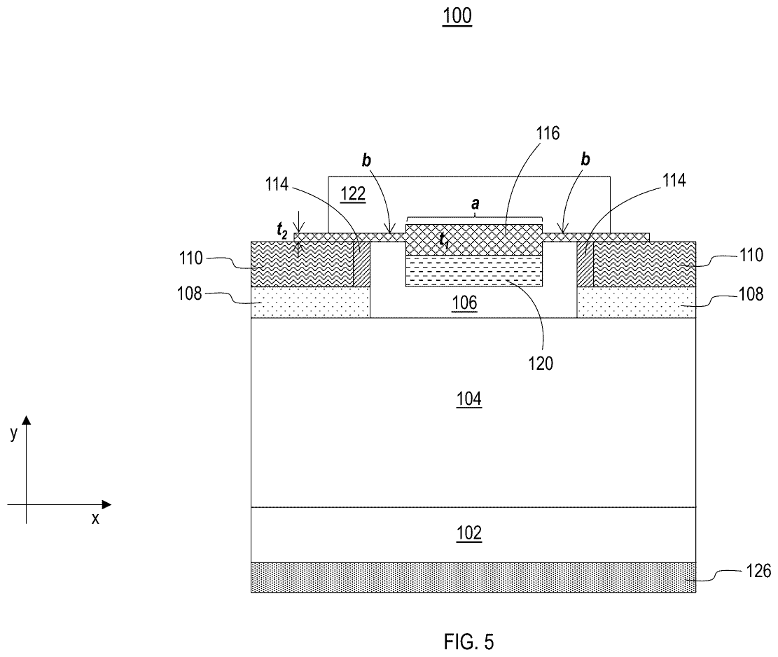

Referring now to FIG. 5, a cross-sectional view of the semiconductor structure 100 is shown after forming a gate electrode 122, according to an embodiment of the present disclosure.

The fabrication process continues by forming the gate electrode 122 above the oxide layer 116. The process of forming gate electrode 122 usually includes depositing a conductive material, such as polysilicon, above the oxide layer 116. The gate electrode 122 and gate oxide 116 provide a gate structure for the semiconductor structure 100. As shown in the figure, the thicker first portion a of the oxide layer 116 extends upward (y-direction) into the gate electrode 122 and downward (−y-direction) into the third semiconductor region 106. The thinner portions b of the oxide layer 116 extend laterally (x-direction), covering an upper surface of the first semiconductor region 106, an upper surface of the channel regions 114, and partially covering an upper surface of the source regions 110.

The integration of a thicker oxide region (i.e., first portion a of the oxide layer 116) and a P-shield underneath (i.e., third semiconductor region 120) can enhance electrostatic control, reduce short channel effects, stabilize threshold voltage, lower leakage currents, increase breakdown voltage, improve reliability, and enhance thermal stability. This combination results in a more efficient and reliable semiconductor structure 100, particularly in high-performance applications.

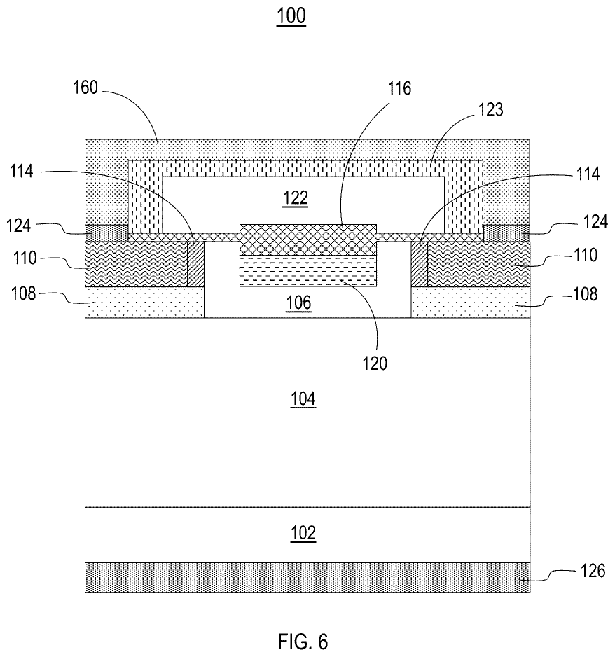

Referring now to FIG. 6, a cross-sectional view of the semiconductor structure 100 is shown after forming an interlevel dielectric layer 123 above the gate electrode 122, a top metal layer 124, and a conductive material 160, according to an embodiment of the present disclosure.

In an embodiment, the interlevel dielectric layer 123 can be formed to fill voids and electrically isolate the gate electrode 122 from active regions within the semiconductor structure 100. Interlevel dielectric layer 123 is positioned above gate electrode 122, covering its upper surface and sidewalls, as well as an exposed upper surface of the oxide layer 116 (i.e., areas of the oxide layer 116 not covered by the oxide layer 116). The interlevel dielectric layer 123 can be formed using techniques such as conformal deposition (e.g., CVD) of dielectric materials including, for example, silicon oxide, silicon nitride, and the like.

Following the formation of interlevel dielectric layer 123, an etching process is employed to selectively remove portions of the interlevel dielectric layer 123 from regions corresponding to the source regions 110, specifically from areas of source regions 110 that are not covered by oxide layer 116. This etching process exposes the source regions 110, facilitating the subsequent formation of the top metal layer 124 over the exposed source areas. In certain embodiments, a silicidation process may be utilized to create top metal layer 124. The top metal layer 124 serves as a source terminal or source electrode for establishing electrical contact with source regions 110. In one or more embodiments, conductive material 160 is formed above and in contact with top metal layer 124 to ensure electrical connectivity between semiconductor structure 100 and subsequently fabricated device components.

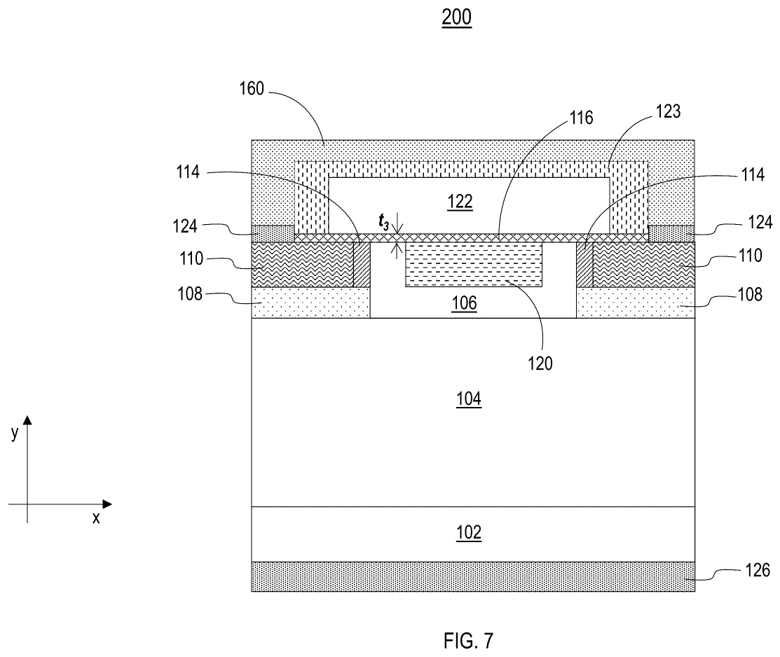

Referring now to FIG. 7, a cross-sectional view of a semiconductor structure 200 is shown depicting an alternate configuration of the oxide layer 116, according to an embodiment of the present disclosure.

In some embodiments, an oxide layer 116 of uniform thickness can be formed above and in contact with the third semiconductor region 120. More particularly, in this case, the oxide layer 116 extends horizontally (x-direction) above an upper surface of the third semiconductor region 120, an upper surface of the first semiconductor region 106 and, at least partially, above an upper surface of the pair of source regions 110. In this embodiment, a thickness t₃ of the uniform oxide layer 116 can vary between approximately 10 nm and approximately 100 nm, and can be formed by thermal oxidation or conformal deposition of an oxide material.

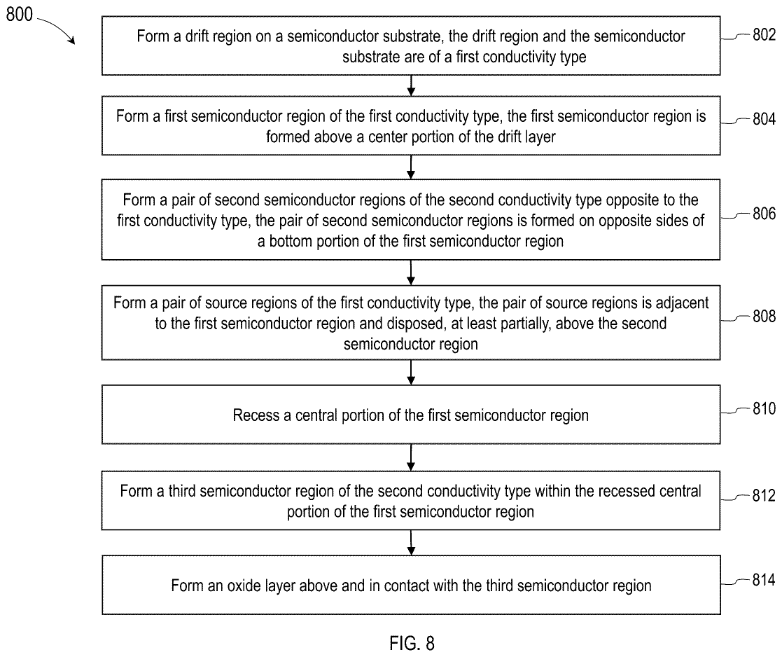

Referring now to FIG. 8, a flowchart 800 depicting operational steps for the fabrication of the semiconductor structure 100 is shown, according to an embodiment of the present disclosure.

The process of forming semiconductor structure 100 starts at step 802 by forming a drift region on a semiconductor substrate. The drift region and the semiconductor substrate are both of a first conductivity type.

At step 804, the process continues by forming a first semiconductor region of the first conductivity type. The first semiconductor region is formed above a center portion of the drift layer. In an embodiment, an impurity concentration of the first semiconductor region is higher than an impurity concentration of the drift layer. In an embodiment, the impurity concentration of the first semiconductor region is more than 1×10¹⁵ cm⁻³ and less than 1×10¹⁸ cm⁻³.

At step 806, a pair of second semiconductor regions of the second conductivity type is formed on opposite sides of a bottom portion of the first semiconductor region. The second conductivity type is opposite to the first conductivity type.

At step 808, the process continues by forming a pair of source regions of the first conductivity type. The pair of source regions is adjacent to the first semiconductor region and is disposed, at least partially, above the second semiconductor region. In an embodiment, an impurity concentration of the pair of source regions is higher than an impurity concentration of the drift layer. In an embodiment, a pair of channel regions is formed between the pair of source regions and the first semiconductor region, with the pair of second semiconductor regions being located between the pair of source regions and the drift layer. In an embodiment, an impurity concentration of the pair of second semiconductor regions is higher than an impurity concentration of the pair of channel regions.

At step 810, the process continues by recessing a central portion of the first semiconductor region.

At step 812, a third semiconductor region of the second conductivity type is formed within the recessed central portion of the first semiconductor region. In an embodiment, forming the third semiconductor region further includes implanting dopant ions of the second conductivity type on an upper surface of the recessed central portion of the first semiconductor region. In an embodiment, an impurity concentration of the third semiconductor region is more than 1×10¹⁵ cm⁻³ and less than 1×10¹⁹ cm⁻³.

At step 814, an oxide layer is formed above and in contact with the third semiconductor region. In an embodiment, a first portion of the oxide layer is disposed above and in contact with the third semiconductor region with the first portion of the oxide layer having a first thickness, while a second portion of the oxide layer adjacent to the first portion is disposed above an upper surface of the first semiconductor region and, at least partially, above an upper surface of the pair of source regions with the second portion of the oxide layer having a second thickness. In an embodiment, the first thickness can be 10 nm or more and 10,000 nm or less, while the second thickness can be 10 nm or more and 100 nm or less. In an embodiment, a main component of the oxide layer includes silicon oxide (SiOx).

In an embodiment, after forming the oxide layer, a gate electrode is formed above the oxide layer, a source electrode is formed above and in contact with the pair of source regions, and a drain electrode is formed on a bottom surface of the semiconductor substrate. In an embodiment, the gate electrode is electrically connected to the first semiconductor region, the source electrode is electrically connected to the pair of source regions; and the drain electrode is electrically connected to the drift layer.

In an embodiment, the first thickness of the first portion of the oxide layer is greater than the second thickness such that the first portion of the oxide layer extends upward into the gate electrode and downward into the recessed central portion of the first semiconductor region directly above the third semiconductor region.

In another embodiment, the first thickness of the first portion of the oxide layer is equal to the second thickness such that the second portion of the oxide layer uniformly extends (in the x-direction) between a bottom surface of the gate electrode and an upper surface of the third semiconductor region, the second portion of the oxide layer further extending in a horizontal direction above an upper surface of the first semiconductor region and, at least partially, above an upper surface of the pair of source drain regions.

### EXAMPLES

Example 1. A method of forming a semiconductor structure, comprising:
forming a drift region on a semiconductor substrate, the drift region and the semiconductor substrate being of a first conductivity type;
forming a first semiconductor region of the first conductivity type, the first semiconductor region being formed above a center portion of the drift layer;
forming a pair of second semiconductor regions of a second conductivity type opposite to the first conductivity type, the pair of second semiconductor regions being formed on opposite sides of a bottom portion of the first semiconductor region;
forming a pair of source regions of the first conductivity type, the pair of source regions being adjacent to the first semiconductor region and disposed, at least partially, above the second semiconductor region;
recessing a central portion of the first semiconductor region;
forming a third semiconductor region of the second conductivity type within the recessed central portion of the first semiconductor region; and
forming an oxide layer above and in contact with the third semiconductor region.

Example 2. The method according to Example 1, further comprising:
forming a gate electrode above the oxide layer;
forming a source electrode above and in contact with the pair of source regions; and
forming a drain electrode on a bottom surface of the semiconductor substrate.

Example 3. The method according to Example 1, wherein forming the third semiconductor region includes:
implanting dopant ions of the second conductivity type on an upper surface of the recessed central portion of the first semiconductor region.

Example 4. The method according to Example 1, wherein a first portion of the oxide layer is disposed above and in contact with the third semiconductor region, the first portion of the oxide layer having a first thickness.

Example 5. The method according to Example 4, wherein a second portion of the oxide layer adjacent to the first portion is disposed above an upper surface of the first semiconductor region and, at least partially, above an upper surface of the pair of source regions, the second portion of the oxide layer having a second thickness.

Example 6. The method according to Examples 2 or 5, wherein the first thickness is greater than the second thickness such that the first portion of the oxide layer extends upward into the gate electrode and downward into the recessed central portion of the first semiconductor region.

Example 7. The method according to Examples 2 or 5, wherein the first thickness is equal to the second thickness such that the second portion of the oxide layer uniformly extends between a bottom surface of the gate electrode and an upper surface of the third semiconductor region, the second portion of the oxide layer further extending in a horizontal direction above an upper surface of the first semiconductor region and, at least partially, above an upper surface of the pair of source drain regions.

Example 8. The method according to Examples 4 or 5, wherein:
the first thickness is 10 nm or more and 10,000 nm or less; and
the second thickness is 10 nm or more and 100 nm or less.

Example 9. The method according to Example 1, wherein an impurity concentration of the first semiconductor region is higher than an impurity concentration of the drift layer.

Example 10. The method according to Example 1, wherein an impurity concentration of the pair of source regions is higher than an impurity concentration of the drift layer.

Example 11. The method according to Example 1, wherein an impurity concentration of the first semiconductor region is more than 1×10¹⁵ cm⁻³ and less than 1×10¹⁸ cm⁻³.

Example 12. The method according to Example 1, wherein an impurity concentration of the third semiconductor region is more than 1×10¹⁵ cm⁻³ and less than 1×10¹⁹ cm⁻³.

Example 13. The method according to Example 1, wherein a main component of the oxide layer includes silicon dioxide.

Example 14. The method according to Example 1, wherein a pair of channel regions is formed between the pair of source regions and the first semiconductor region, wherein the pair of second semiconductor regions is located between the pair of source regions and the drift layer.

Example 15. The method according to Examples 1 or 14, wherein an impurity concentration of the pair of second semiconductor regions is higher than an impurity concentration of the pair of channel regions.

Example 16. The method according to Examples 1 or 2, wherein
the gate electrode is electrically connected to the first semiconductor region;
the source electrode is electrically connected to the pair of source regions; and
the drain electrode is electrically connected to the drift layer.

Example 17. A method of forming a semiconductor structure, comprising:
forming a semiconductor substrate of a first conductivity type;
forming a drift layer of the first conductivity type, the drift layer being disposed above an upper surface of the semiconductor substrate;
forming a first semiconductor region of the first conductivity type above a center portion of the drift layer;
forming a pair of second semiconductor regions of the second conductivity type, the pair of second semiconductor regions laterally abutting a bottom portion of the first semiconductor region;
forming a pair of source regions of the first conductivity type adjacent to the first semiconductor region, the pair of source regions being disposed, at least partially, above the second semiconductor region;
forming a third semiconductor region of the second conductivity type within a recessed central portion of the first semiconductor region;
forming an oxide layer above the third semiconductor region, first semiconductor region, and the pair of source regions, the oxide layer including:
   a first portion above and in contact with the third semiconductor region, the first portion having a first thickness; and
   a second portion disposed above an upper surface of the first semiconductor region and, at least partially, above an upper surface of the pair of source regions, the second portion of the oxide layer having a second thickness.

Example 18. The method according to Example 17, further comprising:
forming a gate electrode above the oxide layer;
forming a source electrode above the pair of source regions; and
forming a drain electrode on the bottom surface of the semiconductor substrate.

Example 19. The method according to Examples 17 or 18, wherein the first thickness is greater than the second thickness such that the first portion of the oxide layer extends upward into the gate electrode and downward into the recessed central portion of the first semiconductor region directly above the third semiconductor region.

Example 20. The method according to Examples 17 or 18, wherein the first thickness is equal to the second thickness such that the second portion of the oxide layer uniformly extends between a bottom surface of the gate electrode and an upper surface of the third semiconductor region, the second portion of the oxide layer further extending in a horizontal direction above an upper surface of the first semiconductor region and, at least partially, above an upper surface of a pair of source drain regions.

The terminology used herein is for the purpose of describing particular embodiments only and is not intended to be limiting of the disclosure. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. “Optional” or “optionally” means that the subsequently described event or circumstance may or may not occur, and that the description includes instances where the event occurs and instances where it does not.

Spatially relative terms, such as “inner,” “outer,” “beneath,” “below,” “lower,” “above,” “upper,” “top,” “bottom,” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” may encompass both an orientation of above and below. The device may be otherwise oriented (rotated 90 degrees or at other orientations) and the spatially relative descriptors used herein interpreted accordingly.

Approximating language, as used herein throughout the specification and claims, may be applied to modify any quantitative representation that could permissibly vary without resulting in a change in the basic function to which it is related. Accordingly, a value modified by a term or terms, such as “about”, “approximately” and “substantially”, are not to be limited to the precise value specified. In at least some instances, the approximating language may correspond to the precision of an instrument for measuring the value. Here and throughout the specification and claims, range limitations may be combined and/or interchanged, such ranges are identified and include all the sub-ranges contained therein unless context or language indicates otherwise. “Approximately” as applied to a particular value of a range applies to both values, and unless otherwise dependent on the precision of the instrument measuring the value, may indicate +/−10% of the stated value(s).

The descriptions of the various embodiments of the present disclosure have been presented for purposes of illustration, but are not intended to be exhaustive or limited to the embodiments disclosed. Many modifications and variations will be apparent to those of ordinary skill in the art without departing from the scope of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A semiconductor structure comprising:
a semiconductor substrate of a first conductivity type having an upper surface and a bottom surface, the semiconductor substrate including silicon carbide;
a drift layer of the first conductivity type is positioned on the upper surface of the semiconductor substrate,
a pair of source regions of the first conductivity type disposed on the drift layer,
a first semiconductor region of the first conductivity type located above a center portion of the drift layer such that the first semiconductor region is sandwiched between the pair of source regions;
a pair of second semiconductor regions of a second conductivity type opposite to the first conductivity type laterally abutting a bottom portion of the first semiconductor region;
a third semiconductor region of the second conductivity type embedded within the first semiconductor region; and
an oxide layer located, at least partially, within the first semiconductor region and extending above an upper surface of the first semiconductor region.

2. The semiconductor structure according to claim 1, further comprising:
a gate electrode located above the oxide layer, a first portion of the oxide layer extending vertically into the gate electrode and a second portion of the oxide layer extending horizontally above the first semiconductor region, the second portion of the oxide layer extending horizontally partially covering the pair of source regions, wherein a thickness of the first portion of the oxide layer is greater than a thickness of the second portion of the oxide layer;
a source electrode positioned above the pair of source regions; and
a drain electrode disposed on the bottom surface of the semiconductor substrate.

3. The semiconductor structure according to claim 2, wherein the oxide layer extend horizontally above an upper surface of the first semiconductor region, an upper surface of the third semiconductor region, and partially above an upper surface of the pair of source regions such that the thickness of the first portion of the oxide layer is the same as the thickness of the second portion of the oxide layer.

4. The semiconductor structure according to claim 2, wherein:
a thickness of the first portion of the oxide layer is 10 nm or more and 10,000 nm or less; and
a thickness of the second portion of the oxide layer is 10 nm or more and 100 nm or less.

5. The semiconductor structure according to claim 1, wherein the third semiconductor region is directly connected with a bottom surface of the oxide layer.

6. The semiconductor structure according to claim 1, wherein an impurity concentration of the first semiconductor region is higher than an impurity concentration of the drift layer.

7. The semiconductor structure according to claim 1, wherein an impurity concentration of the pair of source regions is higher than an impurity concentration of the drift layer.

8. The semiconductor structure according to claim 1, wherein an impurity concentration of the first semiconductor region is more than 1×10¹⁹ cm⁻³ and less than 1×10²¹ cm⁻³.

9. The semiconductor structure according to claim 1, wherein an impurity concentration of the third semiconductor region is more than 1×10¹⁶ cm⁻³ and less than 1×10¹⁹ cm⁻³.

10. The semiconductor structure according to claim 1, wherein the oxide layer includes silicon dioxide as a main component.

11. The semiconductor structure according to claim 1, wherein a pair of channel regions is located between the pair of source regions and the first semiconductor region, wherein the pair of second semiconductor regions is located between the pair of source regions and the drift layer.

12. The semiconductor structure according to claim 1, wherein an impurity concentration of the pair of second semiconductor regions is higher than an impurity concentration of a pair of channel regions.

13. The semiconductor structure according to claim 2, wherein:
the gate electrode is electrically connected to the first semiconductor region;
the source electrode is electrically connected to the pair of source regions; and
the drain electrode is electrically connected to the drift layer.

14. A semiconductor structure comprising:
a semiconductor substrate of a first conductivity type;
a drift layer of the first conductivity type disposed above an upper surface of the semiconductor substrate;
a first semiconductor region of the first conductivity type disposed above a center portion of the drift layer;
a pair of second semiconductor regions of a second conductivity type laterally abutting a bottom portion of the first semiconductor region;
a pair of source regions of the first conductivity type adjacent to the first semiconductor region and disposed, at least partially, above the second semiconductor region;
a third semiconductor region of the second conductivity type disposed within a recessed central portion of the first semiconductor region;
a first portion of an oxide layer disposed above and in contact with the third semiconductor region, the first portion of the oxide layer having a first thickness; and
a second portion of the oxide layer disposed above an upper surface of the first semiconductor region and, at least partially, above an upper surface of the pair of source regions, the second portion of the oxide layer having a second thickness.

15. The semiconductor structure according to claim 14, further comprising:
a gate electrode located above the oxide layer;
a source electrode positioned above the pair of source regions; and
a drain electrode located on a bottom surface of the semiconductor substrate.

16. The semiconductor structure according to claim 15, wherein the first thickness is greater than the second thickness such that the first portion of the oxide layer extends upward into the gate electrode and downward into the recessed central portion of the first semiconductor region directly above the third semiconductor region.

17. The semiconductor structure according to claim 14, wherein the first thickness is equal to the second thickness.

18. The semiconductor structure according to claim 14, wherein:
the first thickness is 10 nm or more and 10,000 nm or less; and
the second thickness is 10 nm or more and 100 nm or less.

19. The semiconductor structure according to claim 14, wherein an impurity concentration of the third semiconductor region is more than 1×10¹⁶ cm⁻³ and less than 1×10¹⁹ cm⁻³.

20. A semiconductor structure comprising:
a semiconductor substrate of a first conductivity type;
a drift layer of the first conductivity type disposed above an upper surface of the semiconductor substrate;
a first semiconductor region of the first conductivity type disposed above a center portion of the drift layer;
a pair of second semiconductor regions of a second conductivity type laterally abutting a bottom portion of the first semiconductor region;
a pair of source regions of the first conductivity type adjacent to the first semiconductor region and disposed, at least partially, above the second semiconductor region;
a third semiconductor region of the second conductivity type disposed within a recessed central portion of the first semiconductor region;
an oxide layer laterally extending above an upper surface of the third semiconductor region, an upper surface of the first semiconductor region and, at least partially, above an upper surface of a pair of source drain regions, wherein the oxide layer has a uniform thickness; and
a gate electrode disposed above the oxide layer.
